(19) United States
(12) Patent Application Publication
(10) Pub. No.: US 2024/0147795 A1
(43) Pub. Date: May 2, 2024

(54) ORGANIC DEVICE AND METHOD FOR MANUFACTURING THE SAME

(71) Applicant: CANON KABUSHIKI KAISHA, Tokyo (JP)

(72) Inventors: HIDESHI KUWABARA, Kanagawa (JP); KENTARO SUZUKI, Kanagawa (JP)

(21) Appl. No.: 18/497,789

(22) Filed: Oct. 30, 2023

(30) Foreign Application Priority Data
Oct. 31, 2022 (JP) 2022-174678

(51) Int. Cl. H10K 59/131; H10K 59/80

(52) U.S. Cl. CPC H10K 59/131; H10K 59/873

(57) ABSTRACT

An organic device includes a pixel region which is disposed above a first main surface of a substrate and in which a plurality of pixels are disposed, a peripheral region disposed outside the pixel region above the first main surface, an external connection electrode disposed in the peripheral region above the first main surface, a first sealing film disposed above the external connection electrode, and a second sealing film which is disposed above the external connection electrode and a material of which is different from a material of the first sealing film, wherein the second sealing film is disposed above the first sealing film, and in the peripheral region, the organic device is provided with, in the first sealing film, an opening which exposes the external connection electrode and, between the opening and the pixel region, a first groove in which the second sealing film is disposed.

### BACKGROUND OF THE INVENTION

### Field of the Invention

The present disclosure relates to an organic device and a method for manufacturing the same.

### Description of the Related Art

An organic electroluminescence element (hereinafter, also referred to as an “organic EL element”, an “organic light emitting element”, or an “organic device”) is an element that emits light when an organic compound layer that includes an anode, a cathode, and a light emitting layer disposed between the anode and the cathode is energized.

Today, the organic device is significantly advanced, and higher performance (increases in definition, brightness, and color purity) and high reliability of the organic device are demanded.

An organic device in which a first sealing layer and a second sealing layer are laminated on an upper electrode is described in Japanese Patent Laid-Open No. 2018-73760.

For the organic device described in Japanese Patent Laid-Open No. 2018-73760, first etching is performed after the first sealing layer has been deposited. After that, the second sealing layer is deposited, and second etching is performed. At this time, etching is performed such that a position of the second etching and a position having been subjected to the first etching overlap each other. As a result, a surface of an external connection electrode of the organic device described in Japanese Patent Laid-Open No. 2018-73760 is likely to be damaged by the etching. Consequently, in some cases the external connection electrode may corrode.

### SUMMARY OF THE INVENTION

The present disclosure is made in view of the above and provides an organic device in which corrosion of the external connection electrode is reduced.

The organic device according to the present disclosure includes a pixel region which is disposed above a first main surface of a substrate and in which a plurality of pixels are disposed, a peripheral region which is disposed outside the pixel region above the first main surface, an external connection electrode which is disposed in the peripheral region above the first main surface, a first sealing film disposed above the external connection electrode, and a second sealing film which is disposed above the external connection electrode and a material of which is different from a material of the first sealing film. The second sealing film is disposed above the first sealing film. In the peripheral region, the organic device is provided with, in the first sealing film, an opening which exposes the external connection electrode and, between the opening and the pixel region, a first groove in which the second sealing film is disposed.

Further features of the present disclosure will become apparent from the following description of exemplary embodiments with reference to the attached drawings.

### BRIEF DESCRIPTION OF THE DRAWINGS

FIG. 1A is a plan view of an organic device according to a first embodiment of the present disclosure. FIG. 1B is a sectional view of the present disclosure taken along line IB-IB of FIG. 1A. FIG. 1C is an enlarged view of part of the present disclosure illustrated in FIG. 1B.

FIGS. 2A to 2D illustrate a method for manufacturing the organic device according to the first embodiment of the present disclosure.

FIG. 3A is a plan view of an organic device according to a second embodiment of the present disclosure. FIG. 3B is a sectional view of the present disclosure taken along line IIIB-IIIB of FIG. 3A.

FIG. 4 is a sectional view of an organic device according to a third embodiment of the present disclosure.

FIGS. 5A and 5B are plan views of an organic device according to a fourth embodiment.

FIG. 6A is a plan view of an organic device described in Japanese Patent Laid-Open No. 2018-73760. FIG. 6B is a sectional view taken along line VIB-VIB of FIG. 6A.

FIG. 7 is a schematic view illustrating an example of a display apparatus according to an embodiment of the present disclosure.

FIG. 8A is a schematic view illustrating an example of an image capturing apparatus according to an embodiment of the present disclosure. FIG. 8B is a schematic view illustrating an example of an electronic device according to an embodiment of the present disclosure.

FIG. 9A is a schematic view illustrating an example of a display apparatus according to an embodiment of the present disclosure. FIG. 9B is a schematic view illustrating an example of a foldable display apparatus.

FIG. 10A is a schematic view illustrating an example of a lighting apparatus according to an embodiment of the present disclosure. FIG. 10B is a schematic view illustrating an example of an automobile including a vehicle light fitting according to an embodiment of the present disclosure.

FIG. 11A is a schematic view illustrating an example of a wearable device according to an embodiment of the present disclosure. FIG. 11B is a schematic view illustrating an example of a wearable device according to an embodiment of the present disclosure in a form in which the wearable device includes image capturing apparatuses.

### DESCRIPTION OF THE EMBODIMENTS

Hereinafter, embodiments of the present disclosure will be described in detail with reference to the accompanying drawings.

The following embodiments do not limit the disclosure relating to the scope of the claims. Although a plurality of features are described in the embodiments, not all of the plurality of features are necessarily required. In addition, the plurality of features may be arbitrarily combined with each other. Furthermore, in the accompanying drawings, the same or similar elements are denoted by the same reference numerals, and thereby redundant description thereof is omitted.

Furthermore, herein, a capability of reducing corrosion of an external connection electrode may be described as to have “a high reliability”.

### First Embodiment

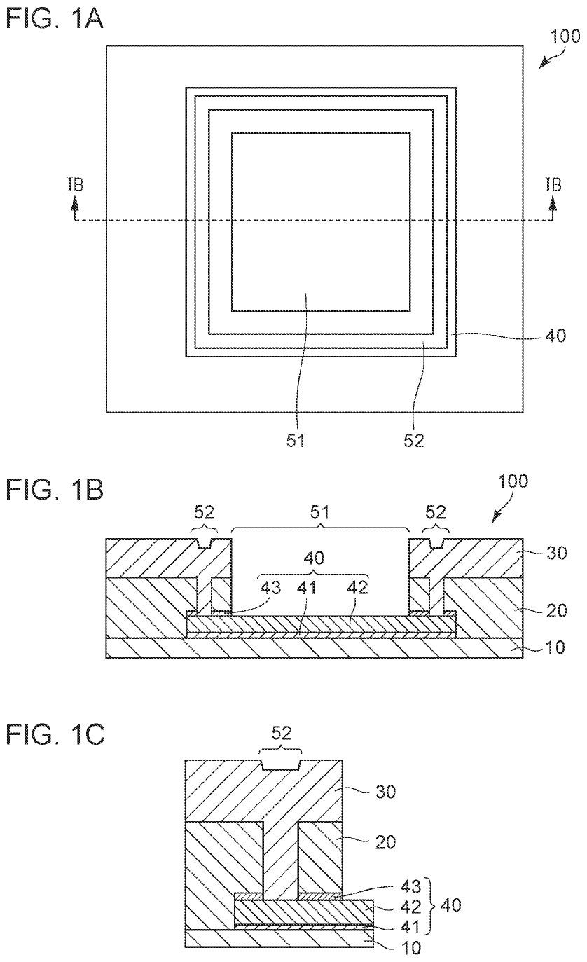

An organic device 100 according to a first embodiment is described with reference to FIGS. 1A to 1C. FIG. 1A is a plan view of the organic device 100 according to the first embodiment, FIG. 1B is a sectional view taken along line IB-IB of FIG. 1A, and FIG. 1C is an enlarged view of a first groove 52. The organic device 100 includes a substrate 10 having a first main surface, a pixel region which is above the first main surface and in which a plurality of pixels are disposed, a peripheral region which is disposed outside the pixel region above the first main surface and in which no pixel is disposed, an external connection electrode 40 disposed in the peripheral region, and a first sealing film 20 and a second sealing film 30 disposed above the external connection electrode 40. The second sealing film 30 is disposed above the first sealing film 20. The peripheral region included in the organic device 100 may have a form in which no pixel is disposed.

The pixel region may be disposed on the first main surface. The peripheral region may be disposed on the first main surface. The external connection electrode 40 may be disposed on the first main surface. The first sealing film 20 may be disposed the external connection electrode. The second sealing film 30 may be disposed on the external connection electrode 40. The second sealing film 30 may be disposed on the first sealing film 20.

In the peripheral region, the organic device 100 has an opening 51 that exposes the external connection electrode 40 and the first groove 52 which is disposed between the opening 51 and the pixel region and in which the second sealing film 30 is disposed. The opening 51 is also referred to as a pad opening. The first groove 52 can be formed so as to expose the external connection electrode 40 or the substrate 10 disposed in the peripheral region. Particularly, the first groove 52 can be formed so as to expose the external connection electrode 40.

The reason for this is that, when the first groove 52 is formed so as to expose the external connection electrode 40, penetration of moisture can be further reduced.

In the organic device 100 according to the present disclosure, it can be said that, in plan view of the first main surface, the opening 51, the first sealing film 20, the second sealing film 30, and the first sealing film 20 are provided in this order in a direction parallel to the first main surface.

The substrate 10 may be a semiconductor substrate such as a silicon substrate, a glass substrate, or a resin substrate. The substrate 10 includes an interlayer insulating layer and a planarization layer on the substrate 10. A transistor may be disposed in the interlayer insulating layer or the planarization layer. When the substrate 10 is formed by a sealing film, the substrate 10 can be formed of silicon oxide (SiO) or silicon nitride (SiN). Particularly, the substrate 10 can be formed of SiO. The reason for this is that, compared to SiN, SiO is easily processed.

The first sealing film 20 or the second sealing film 30 is not limited as long as the materials of the first sealing film 20 and the second sealing film 30 are different from each other and the first sealing film 20 and the second sealing film 30 can reduce penetration of moisture into the organic device 100. However, the moisture permeability of the second sealing film 30 can be lower than the moisture permeability of the first sealing film 20. Specifically, the first sealing film 20 can be a film that contains SiO, and the second sealing film 30 can be a film that contains SiN. When the organic device 100 has the above-described configuration, penetration of moisture into the organic device 100 can be further reduced. Thus, the organic device 100 has a higher reliability.

The second sealing film 30 is disposed in the first groove 52 to reduce penetration of moisture into the organic device 100. At this time, in the first groove 52, the second sealing film 30 can be disposed so as to be in contact with the substrate 10 or the external connection electrode 40, particularly, the second sealing film 30 can be disposed so as to be in contact with the external connection electrode 40, and, more particularly, the second sealing film 30 can be disposed so as to fill the first groove 52. When the organic device 100 has the above-described configuration, penetration of moisture into the organic device 100 can be further reduced.

Although a method for depositing the first sealing film 20 or the second sealing film 30 is not particularly limited, the first sealing film 20 and the second sealing film 30 can be deposited by a chemical vapor deposition (CVD), and particularly, can be deposited by especially a plasma CVD method.

Specifically, the external connection electrode 40 is a pad electrode or the like and includes a barrier metal 41, an Al alloy 42, and an antireflection film 43. The barrier metal 41 and the antireflection film 43 may be formed of titanium nitride (TiN). The Al alloy 42 may be Al containing Cu. Specifically, the Al alloy 42 may contain 0.2 to 1% of Cu by weight in Al. The external connection electrode 40 is connected to a flexible cable by using an anisotropic conductive film (ACF) or the like. A wiring electrode of the external connection electrode 40 may be exposed at an external connection electrode surface.

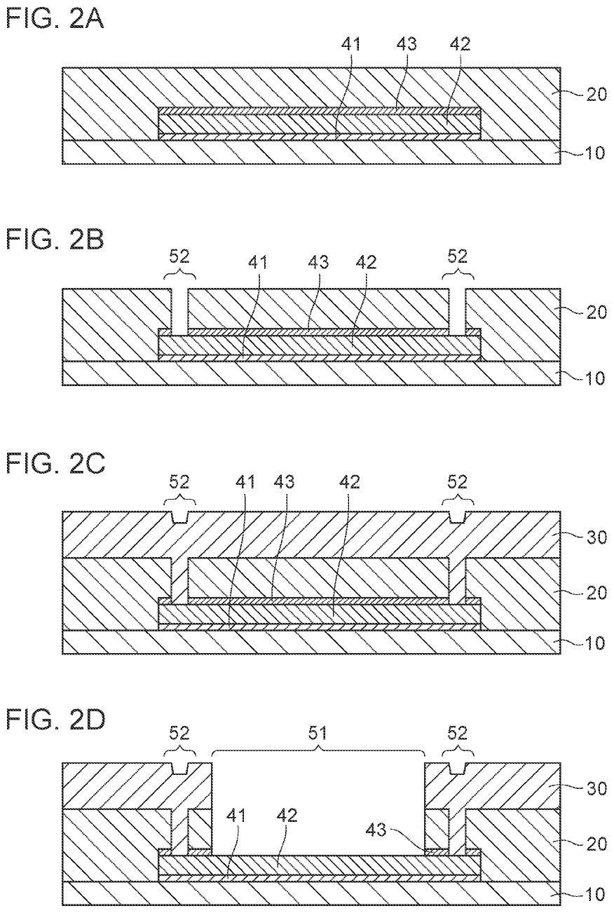

Hereinafter, a method for manufacturing the organic device 100 according to the first embodiment is described with reference to FIGS. 2A to 2D. First, as exemplified in FIG. 2A, the organic device 100 in which the external connection electrode 40 and the first sealing film 20 are disposed above the substrate 10 is prepared. At this time, the first sealing film 20 may be deposited by using the plasma CVD method. Also, a surface of the first sealing film 20 may be planarized through a chemical mechanical polishing (CMP) process.

Next, as exemplified in FIG. 2B, the first groove 52 is formed in the first sealing film 20 by etching. The first groove 52 is formed so as to expose the substrate 10 disposed in the peripheral region or the external connection electrode 40.

When the first groove 52 is formed so as to expose the substrate 10, the substrate 10 can be formed of SiN. Etching of the first sealing film 20 is, for example, plasma etching (reactive ion etching (RIE)) using a fluorine-related gas. Specifically, the fluorine-related gas may be C₄F₈ or CF₄. When the first groove 52 is formed so as to expose the external connection electrode 40, the antireflection film 43 may be etched at the same time. As illustrated in FIG. 1A, the first groove 52 formed by using the above-described technique is disposed between the opening 51, which will be described later, and the substrate 10 disposed in the peripheral region. In other words, as illustrated in FIG. 1B, the first groove 52 is formed on the outer edge side, relative to the opening 51, of the external connection electrode 40.

Next, as exemplified in FIG. 2C, the second sealing film 30 is formed above the first sealing film 20. The second sealing film 30 is deposited by using, for example, the plasma CVD method.

An alumina (Al₂O₃) film may be included between the first sealing film 20 and the second sealing film 30. The alumina film is formed by using, for example, an atomic layer deposition (ALD) method. When the second sealing film 30 is disposed in the first groove 52, penetration of moisture into the organic device 100 can be reduced.

At last, as illustrated in FIG. 2D, the first sealing film 20 and the second sealing film 30 are etched so as to form the opening 51. The opening 51 is formed so as to expose the external connection electrode 40. Etching of the first sealing film 20 and the second sealing film 30 is, for example, plasma etching (RIE) using a fluorine-related gas. Specifically, the fluorine-related gas may be C₄F₈ or CF₄. At this time, the antireflection film 43 may be etched at the same time.

By performing the above-described method for manufacturing, the organic device 100 having the configuration illustrated in FIG. 1B can be obtained. The organic device 100 according to the present disclosure can reduce penetration of moisture and reduce damage to the external connection electrode 40 due to the etching. Thus, the organic device having a high reliability can be obtained.

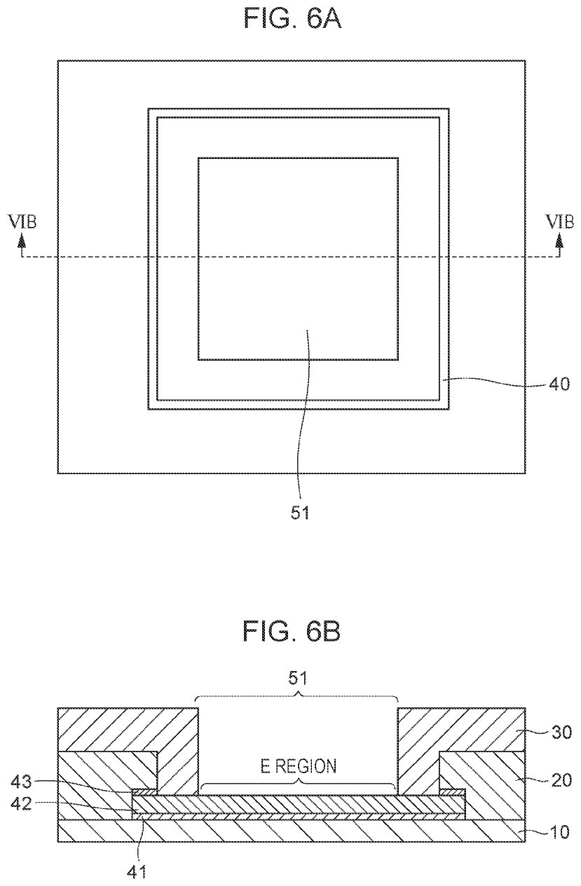

Hereinafter, with reference to FIG. 2D and FIGS. 6A and 6B, the present disclosure and a comparative example are compared.

FIG. 6A is a plan view of an organic device described in Japanese Patent Laid-Open No. 2018-73760, and FIG. 6B is a sectional view taken along line VIB-VIB of FIG. 6A. For the organic device described in Japanese Patent Laid-Open No. 2018-73760, the first sealing film 20 is deposited, and then, the opening 51 is formed on the external connection electrode 40 by etching. Then, after the second sealing film 30 has been deposited, the opening 51 is formed again on the external connection electrode 40 by etching. In other words, the external connection electrode 40 is exposed to etching plurality of times in an E region illustrated in FIG. 6B.
As a result, the likelihood of corrosion of the external connection electrode 40 increases.

In contrast, in the organic device 100 according to the present disclosure, etching is performed at different positions out of a surface of the external connection electrode 40. In other words, the opening 51 and the first groove 52 are not redundantly formed at the same position. Thus, for the organic device 100 according to the present disclosure, damage to the surface of the external connection electrode 40 due to etching can be reduced while sealing performance against moisture is maintained. As a result, an organic device in which the external connection electrode 40 is unlikely to corrode and which has a high reliability can be obtained.

### Second Embodiment

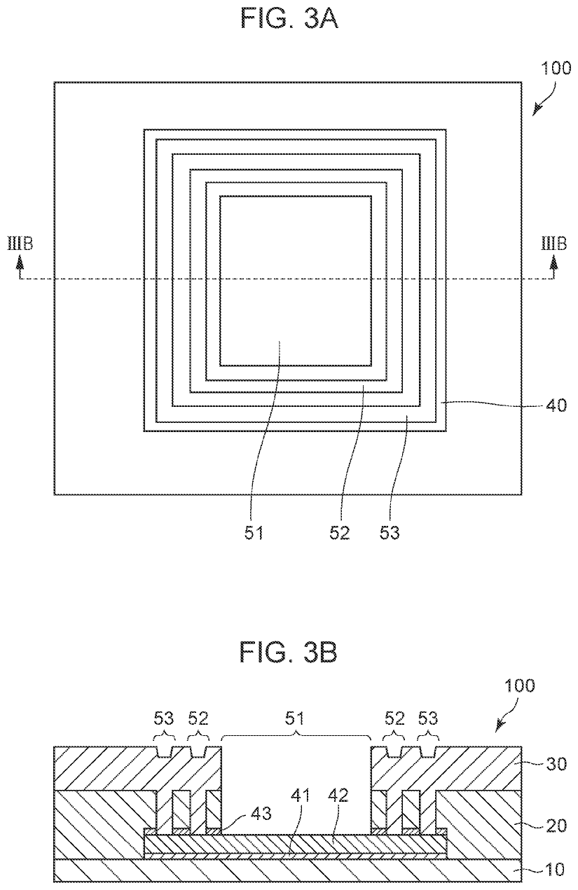

The organic device 100 according to a second embodiment is described with reference to FIGS. 3A and 3B.

FIG. 3A is a plan view of the organic device 100 according to the second embodiment, and FIG. 3B is a sectional view taken along line IIIB-IIIB of FIG. 3A. According to the second embodiment, a second groove 53 in which the second sealing film 30 is disposed is provided between the opening 51 and the pixel region. In other words, as illustrated in FIG. 3B, the second groove 53 is formed on the outer edge side, relative to the opening 51, of the external connection electrode 40. The second groove 53 is formed so as to expose the substrate 10 or the external connection electrode 40. When the second groove 53 is formed so as to expose the substrate 10, the substrate 10 can be formed of SiN. When the second sealing film 30 is disposed in the second groove 53 as illustrated in FIG. 3B, penetration of moisture into the organic device 100 can be further reduced. At this time, in the second groove 53, the second sealing film 30 can be disposed so as to be in contact with the substrate 10 or the external connection electrode 40, and particularly, the second sealing film 30 can be disposed so as to fill the second groove 53. When the organic device 100 has the above-described configuration, penetration of moisture into the organic device 100 can be further reduced. Thus, the organic device 100 according to the present disclosure has a higher reliability.

In the organic device 100 according to the present embodiment, it can be said that, in plan view of the first main surface, the opening 51, the first sealing film 20, the second sealing film 30, the first sealing film 20, the second sealing film 30, and the first sealing film 20 are provided in this order in the direction parallel to the first main surface.

The organic device 100 having the configuration exemplified in FIGS. 3A and 3B can be manufactured by forming the second groove 53 when forming the first groove 52 in the method for manufacturing the organic device 100 according to the first embodiment.

### Third Embodiment

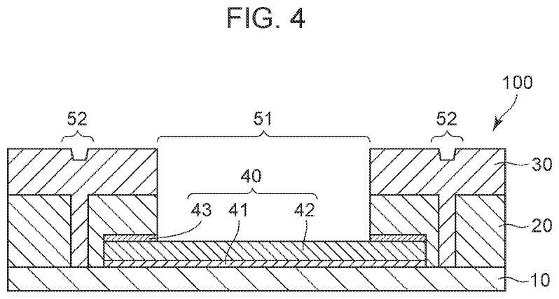

The organic device 100 according to a third embodiment is described with reference to FIG. 4. The third embodiment is a variant of the first embodiment and an organic device in which the first groove 52 is disposed on the substrate 10. When the organic device 100 has the above-described configuration, even when moisture penetrates into the pixel region from the first sealing film 20 facing the opening 51, the moisture is required to penetrate sequentially through the first sealing film 20, the substrate 10, and the first sealing film 20. Thus, even when the organic device 100 has the configuration of the third embodiment, penetration of moisture into the organic device 100 can be further reduced.

In particular, when the organic device 100 has the above-described configuration, the substrate 10 can be formed of SiN. The moisture permeability of SiN is lower than that of SiO. Thus, even when moisture penetrates from the first sealing film 20 facing the opening 51, penetration of the moisture into the pixel region can be further reduced.

### Fourth Embodiment

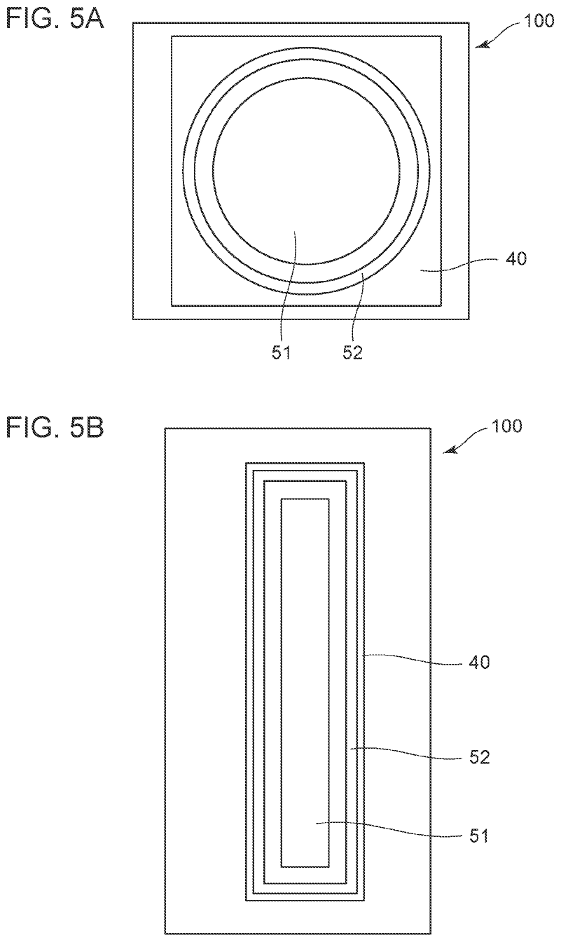

The organic device 100 according to a fourth embodiment is described with reference to FIGS. 5A and 5B.

FIGS. 5A and 5B are plan views of the organic device 100 according to the fourth embodiment. The sectional view of the organic device 100 according to the fourth embodiment is omitted because it is similar to FIG. 1B. The opening 51 and the first groove 52 may have a rectangular shape, a circular shape, or an elliptical shape in accordance with the purposes.

### Application Examples

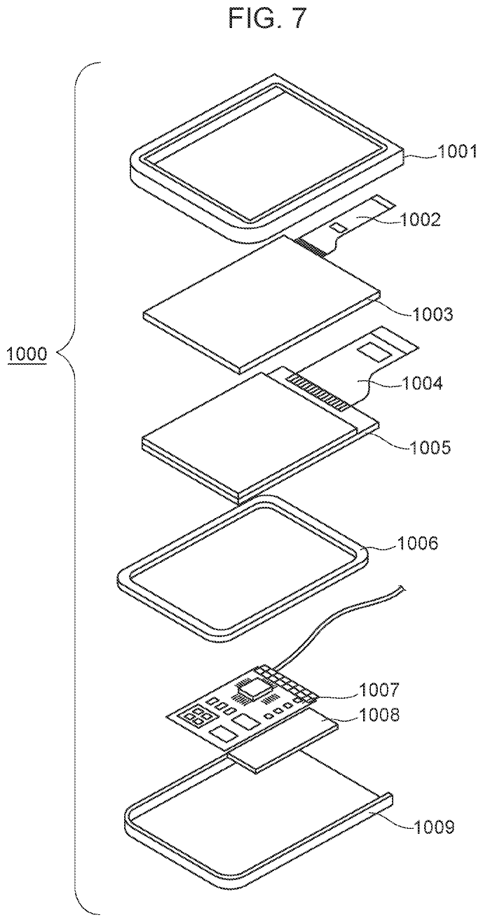

FIG. 7 is a schematic view illustrating an example of a display apparatus according to the present embodiments. A display apparatus 1000 may include a touch panel 1003, a display panel 1005, a frame 1006, a circuit substrate 1007, and a battery 1008 between an upper cover 1001 and a lower cover 1009. Flexible printed circuits (FPCs) 1002 and 1004 are respectively connected to the touch panel 1003 and the display panel 1005. The display panel 1005 may include the organic device according to the present disclosure. Transistors are printed on the circuit substrate 1007.

The battery 1008 is not necessarily provided unless the display apparatus 1000 is a portable device or may be provided at another position even when the display apparatus 1000 is a portable device.

The display apparatus 1000 according to the present embodiment may include red, green, and blue color filters. The red, green, and blue color filters may be disposed in a delta arrangement.

The display apparatus 1000 according to the present embodiment may be used in a display section of an image capturing apparatus including an image capturing element that receives light. The image capturing apparatus may further include an optical section including a lens, and the image capturing element may receive light having passed through the optical section. The optical section may include a single lens or a plurality of lenses. The image capturing apparatus may include a display section that displays information obtained by the image capturing element. The display section may be exposed to the outside of the image capturing apparatus or disposed in a finder. The image capturing apparatus may be a digital camera or a digital video camera.

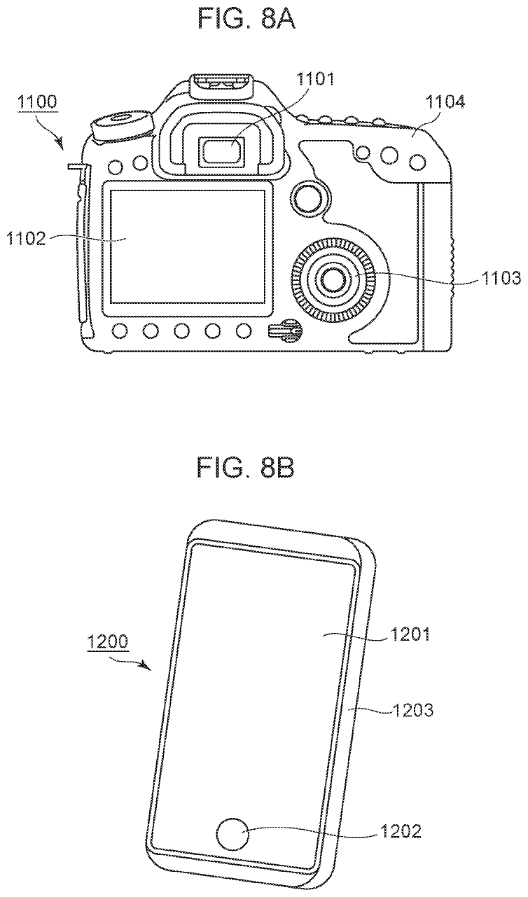

FIG. 8A is a schematic view illustrating an example of an image capturing apparatus according to the present embodiment. An image capturing apparatus 1100 may include a view finder 1101, a rear display 1102, an operation section 1103, and a housing 1104. The view finder 1101 and the rear display 1102 may include the organic device according to the present disclosure. In this case, the display apparatus may display not only an image to be captured but also environmental information, an image capturing instruction, and the like. Examples of the environmental information may include the intensity of external light, the direction of the external light, a moving speed of a subject, a possibility of the subject being shielded by a shield, and the like.

The image capturing apparatus 1100 includes an optical section (not illustrated). When the optical section includes a plurality of lenses, light having passed through the optical section forms an image on an image capturing element housed in the housing 1104. The focus of the plurality of lenses can be adjusted by adjusting the relative positions of the plurality of lenses. This operation may be manually performed or automatically performed. The image capturing apparatus may also be referred to as a photoelectric conversion apparatus.

Methods of capturing an image by using the photoelectric conversion apparatus may include a method in which the difference from a previous image is detected, a method in which an image is cut out from a usually recorded image, and the like instead of sequentially capturing images.

FIG. 8B is a schematic view illustrating an example of an electronic device according to the present embodiment. The electronic device 1200 includes a display section 1201, an operation section 1202, and a housing 1203. The housing 1203 may include a circuit, a printed circuit board having the circuit, a battery, and a communication section. The operation section 1202 may be a button or a reactive section of a touch panel-type. The operation section 1202 may be a biometric recognition section that recognizes a fingerprint to perform unlocking or the like. The electronic device including the communication section may be referred to as a communication device. The electronic device may include a lens and an image capturing element to further have a camera function. Images captured by using the camera function are displayed in the display section 1201. Examples of the electronic device include, for example, a smartphone and a laptop computer.

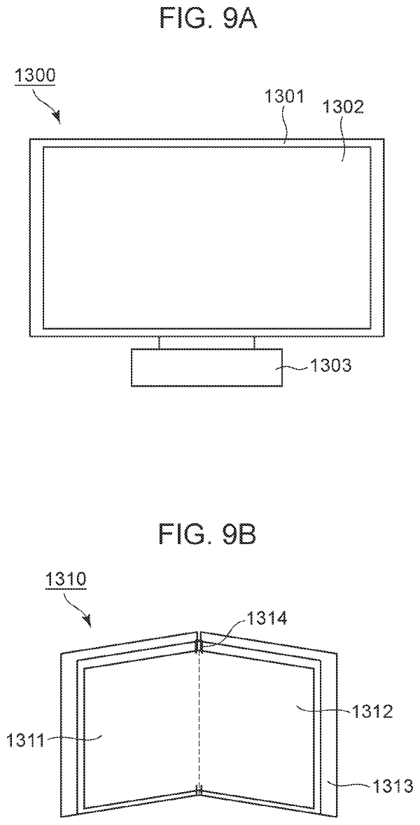

FIGS. 9A and 9B are schematic views illustrating examples of a display apparatus according to the present embodiment. FIG. 9A is a display apparatus such as a television monitor or a PC monitor. A display apparatus 1300 includes a housing 1301 and a display section 1302. The organic device according to the present disclosure may be used in the display section 1302. The display apparatus 1300 may further include a base 1303 that supports the housing 1301 and the display section 1302. The form of the base 1303 is not limited to the form illustrated in FIG. 9A. The lower side of the housing 1301 may serve as the base. Furthermore, the housing 1301 and the display section 1302 may be curved. The radius of curvature of the housing 1301 and the display section 1302 may be greater than or equal to 5000 mm and smaller than or equal to 6000 mm.

FIG. 9B is a schematic view illustrating another example of the display apparatus according to the present embodiment. A display apparatus 1310 illustrated in FIG. 9B is foldable, a so-called foldable display apparatus. The display apparatus 1310 includes a first display section 1311, a second display section 1312, a housing 1313, and a fold point 1314. The first display section 1311 and the second display section 1312 may include the organic device according to the present disclosure. The first display section 1311 and the second display section 1312 may be a single seamless display apparatus. The first display section 1311 and the second display section 1312 can be separated from each other at the fold point 1314. The first display section 1311 and the second display section 1312 may display images different from each other, or the first display section 1311 together with the second display section 1312 may display a single image.

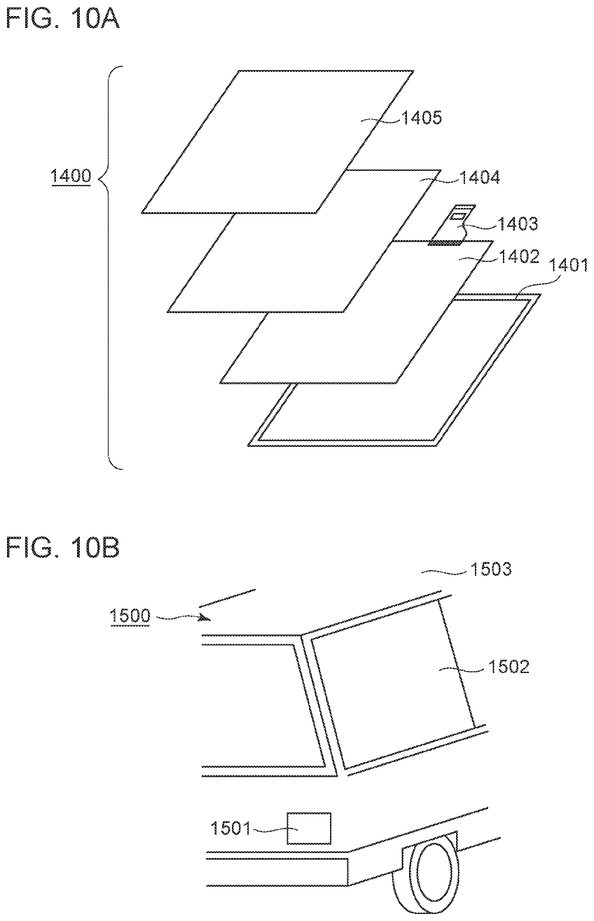

FIG. 10A is a schematic view illustrating an example of a lighting apparatus according to the present embodiment. A lighting apparatus 1400 may include a housing 1401, a light source 1402, and a circuit substrate 1403. The light source 1402 may include the organic device according to the present disclosure. The lighting apparatus 1400 may include an optical film 1404 for improving a color rendition of the light source. Furthermore, the lighting apparatus 1400 may include a light diffusing section 1405 for effectively diffusing the light of the light source. When the lighting apparatus 1400 includes the light diffusing section 1405, the light can be transmitted in a wide range. The optical film 1404 and the light diffusing section 1405 may be provided on a light emitting side of lighting. A cover may be provided an outermost part according to need.

The lighting apparatus is, for example, an indoor lighting apparatus. The lighting apparatus may emit light of any of white, neutral white, and other colors from blue to red. The lighting apparatus may include a light control circuit that controls the light of any of those colors. The lighting apparatus may include a power supply circuit. The power supply circuit may be a circuit that converts an alternating voltage into a direct voltage. White has a color temperature of 4200 K, and neutral white has a color temperature of 5000 K. The lighting apparatus may include a color filter.

Furthermore, the lighting apparatus according to the present embodiment may include a heat dissipation section. The heat dissipation section dissipates heat in the apparatus to the outside of the apparatus and includes metal or ceramic having a high thermal conductivity.

FIG. 10B is a schematic view of an automobile serving as an example of a moving object according to a present embodiment. The automobile includes a taillight serving as an example of a light fitting. An automobile 1500 may include a taillight 1501 and be in a form in which the taillight 1501 is lit up when braking operation or the like is performed. The automobile 1500 may include a car body 1503 and a window 1502 attached to the car body 1503.

The taillight 1501 may include the organic device according to the present disclosure. The taillight 1501 may include a protective member that protects a light source. Although the material of the protective member is not limited as long as the protective member has a certain degree of strength and is transparent, the protective member can be formed of polycarbonate or the like. A furandicarboxylic acid derivative, an acrylonitrile derivative, or the like may be mixed into polycarbonate.

The moving object according to the present embodiment may be an automobile, a vessel, an aircraft, a drone, or the like. The moving object may include a body and a light fitting provided in the body. The light fitting may stay lit up to notify the position of the body.

The electronic device or the display apparatus can be applied to a system that can be worn as a wearable device such as, for example, smart glasses, a head mount display, or smart contact lenses. The electronic device may include an image capturing apparatus that can perform photoelectric conversion on visible light and a display apparatus that can emit visible light.

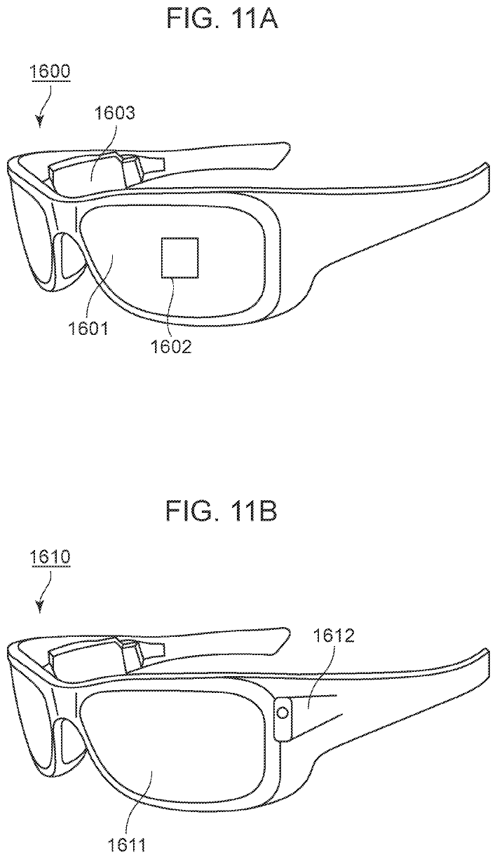

FIGS. 11A and 11B are schematic views illustrating examples of glasses (smart glasses) according to the present embodiment. Referring to FIG. 11A, glasses 1600 (smart glasses) are described. The glasses 1600 include display sections on the rear surface sides of lenses 1601. The display sections may include organic devices according to the present disclosure. Furthermore, image capturing apparatuses 1602 such as complementary metal oxide semiconductor (CMOS) sensors or single photon avalanche diodes (SPADs) may be provided on the front surface sides of the lenses 1601.

The glasses 1600 further include a control apparatus 1603. The control apparatus 1603 functions as a power supply that supplies power to the image capturing apparatuses 1602 and the display sections. Furthermore, the control apparatus 1603 controls operations of the image capturing apparatuses 1602 and the display sections. Optical systems for concentrating light to the image capturing apparatuses 1602 and the display sections are formed in the lenses 1601.

Referring to FIG. 11B, glasses 1610 (smart glasses) are described. The glasses 1610 include control apparatuses 1612 in which display apparatuses including the organic devices according to the present disclosure are provided. The control apparatuses 1612 may further include image capturing apparatuses corresponding to the image capturing apparatuses 1602. Optical systems for projecting light emitted from the control apparatuses 1612 are formed on lenses 1611, and images are projected onto the lenses 1611. The control apparatuses 1612 function as power supplies that supply power to the image capturing apparatuses and the display apparatuses and control operations of the image capturing apparatuses and the display apparatuses. The control apparatuses 1612 may include line-of-sight detection sections that detect the lines of sight of a wearer. To detect the lines of sight, infrared light may be used. An infrared emission sections emit infrared light to the eyeballs of a user who gazes a displayed image. Out of the emitted infrared light, light reflected from the eyeballs is detected by image capturing sections including light receiving elements so as to obtain captured images of the eyeballs. When reducing units that reduce the light from the infrared emission sections to display sections in plan view are provided, degradation of image quality is reduced.

From the captured images of the eyeballs obtained by capturing the infrared light, the control apparatuses 1612 detect the lines of sight of the user to the displayed image. Any known technique can be applied to the line-of-sight detection using captured images of the eyeballs. For example, the line-of-sight detection method based on a Purkinje image due to reflection of light radiated to the corneas can be used.

More specifically, a line-of-sight detection process based on the pupil center corneal reflection method is performed. When a line-of-sight vector representing the direction of the eyeball (rotational angle) is calculated based on the Purkinje image and a pupil image included in the captured image of the eyeball by using the pupil center corneal reflection method, the line of sight of the user is detected.

A display apparatus according to an embodiment of the present disclosure may include an image capturing apparatus including a light receiving element and control a display image of the display apparatus based on line-of-sight information of a user from the image capturing apparatus.

Specifically, the display apparatus determines a first sight region gazed by the user and a second sight region other than the first sight region based on the line-of-sight information. The first sight region and the second sight region may be determined by a control apparatus of the display apparatus. Alternatively, the display apparatus may receive the first sight region and the second sight region determined by an external control apparatus. In a display region of the display apparatus, a display resolution of the first sight region may be controlled to be higher than a display resolution of the second sight region. That is, the resolution of the second sight region may be set to be lower than the resolution of the first sight region.

In determining the first sight region and a display region of high priority, artificial intelligence (AI) may be used. The AI may be a model configured to use, as training data, an image of the eyeball and the direction actually gazed by the eyeball of the image so as to estimate the angle of the line of sight and the distance to an object ahead of the line of sight from an image of the eyeball. The AI may be included in the display apparatus, the image capturing apparatus, or the external apparatus. When the AI is included in the external apparatus, the AI can be applied to smart glasses that further include image capturing apparatuses that capture external images. The smart glasses may display captured external information in real time.

From the above description, the organic device according to the present disclosure can maintain sealing performance against moisture and reduce damage to the external connection electrode due to the etching. Accordingly, the organic device in which corrosion of the external connection electrode is reduced can be provided. Furthermore, of course, the present disclosure is not limited to the above-described embodiments, and the above-described embodiments can be changed or combined with each other as appropriate without departing from the gist of the present disclosure.

According to the present disclosure, the organic device in which corrosion of the external connection electrode is reduced can be provided.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2022-174678, filed Oct. 31, 2022, which is hereby incorporated by reference herein in its entirety.

What is claimed is:

1. An organic device comprising:
a pixel region which is disposed above a first main surface of a substrate and in which a plurality of pixels are disposed;
a peripheral region which is disposed outside the pixel region above the first main surface;
an external connection electrode which is disposed in the peripheral region above the first main surface;
a first sealing film disposed above the external connection electrode; and
a second sealing film which is disposed above the external connection electrode and a material of which is different from a material of the first sealing film,
wherein the second sealing film is disposed above the first sealing film, and
wherein, in the peripheral region, the organic device is provided with, in the first sealing film, an opening which exposes the external connection electrode and, between the opening and the pixel region, a first groove in which the second sealing film is disposed.

2. The organic device according to claim 1,
wherein, in the organic device, the pixels are not disposed in the peripheral region.

3. The organic device according to claim 1,
wherein, in the first groove, the second sealing film is in contact with the external connection electrode.

4. The organic device according to claim 1,
wherein the second sealing film is disposed so as to fill the first groove.

5. The organic device according to claim 1,
wherein a moisture permeability of the second sealing film is smaller than a moisture permeability of the first sealing film.

6. The organic device according to claim 1,
wherein the first sealing film contains silicon oxide.

7. The organic device according to claim 1,
wherein the second sealing film contains silicon nitride.

8. The organic device according to claim 1,
wherein, in plan view of the first main surface, the opening, the first sealing film, the second sealing film, and the first sealing film are provided in this order in a direction parallel to the first main surface.

9. The organic device according to claim 1,
wherein the organic device further has a second groove disposed around the opening, and
the second sealing film is disposed in the second groove.

10. The organic device according to claim 9,
wherein, in the second groove, the second sealing film is in contact with the external connection electrode.

11. The organic device according to claim 9,
wherein the second sealing film is disposed so as to fill the second groove.

12. The organic device according to claim 9,
wherein, in plan view of the first main surface, the opening, the first sealing film, the second sealing film, the first sealing film, the second sealing film, and the first sealing film are provided in this order in a direction parallel to the first main surface.

13. A photoelectric conversion apparatus comprising:
an image capturing element that receives light; and
a display section that displays an image captured by the image capturing element,
wherein the display section is the organic device according to claim 1.

14. A display apparatus comprising:
a display section that includes the organic device according to claim 1; and
a housing in which the display section is provided.

15. An electronic device comprising:
a display section that includes the organic device according to claim 1;
a housing in which the display section is provided; and
a communication section which is provided in the housing and which communicates with an outside.

16. A lighting apparatus comprising:
a light source that includes the organic device according to claim 1; and
a housing in which the light source is provided.

17. A moving object comprising:
a light fitting that includes the organic device according to claim 1; and
a body in which the light fitting is provided.

18. A wearable device comprising:
a display section that includes the organic device according to claim 1;
an optical system that concentrates light to the display section; and
a control apparatus that controls operation of the display section.

19. A method for manufacturing an organic device, the method comprising the steps of:
preparing the organic device that includes a pixel region which is disposed above a substrate and in which a plurality of pixels are disposed, a peripheral region which is disposed outside the pixel region above the substrate, an external connection electrode which is disposed in the peripheral region above the substrate, and a first sealing film disposed above the external connection electrode above the substrate;
forming, in the first sealing film, a first groove that exposes the external connection electrode or the substrate disposed in the peripheral region;
disposing a second sealing film above the first sealing film after the forming of the first groove has been performed; and
forming, after the forming of the second sealing film has been performed, an opening that exposes the external connection electrode.
